(19) United States
(12) Patent Application Publication
(10) Pub. No.: US 2003/0116826 A1
(43) Pub. Date: Jun. 26, 2003

(54) Interconnect structure capped with a metallic barrier layer and method fabrication thereof

(76) Inventors: Chen-Chiu Hsue, Hsinchu (TW); Shyh-Dar Lee, Hsinchu Hsien (TW); Tzu-Kun Ku, Taipei (TW)

Correspondence Address: BIRCH STEWART KOLASCH & BIRCH, PO BOX 747, FALLS CHURCH, VA, 22040-0747, US

(21) Appl. No.: 10/022,508

(22) Filed: Dec. 20, 2001

(51) Int. Cl. H01L 23/58

(52) U.S. Cl. 257/650

(57) ABSTRACT

An interconnect structure has at least two adjacent metal wiring lines patterned on a semiconductor substrate and separated by a gap. A dielectric layer is formed on the metal wiring lines to fill the gap to a predetermined thickness. A metallic barrier layer, which may be of Ti, TiN, Ta, TaN, Cu or copper alloys are sandwiched between the sidewall of the metal wiring line and the dielectric layer. In addition, a contact plug passing through the dielectric layer is electrically connected to the top of the metal wiring line.

### BACKGROUND OF THE INVENTION

1. Field of the Invention

The present invention relates to an interconnect structure in highly integrated semiconductor circuits and, more particularly, to an interconnect structure capped with a metallic barrier layer and a method of fabricating thereof.

2. Description of the Related Art

In the fabrication of ultra-large-scale integration (ULSI) circuits, a plurality of metal wiring lines at different levels, serving as multilevel interconnect structures, are used to increase circuit performance and the functional complexity of the circuits. An inter-metal dielectric (IMD) layer, typically of low-k dielectric materials, is required to completely fill the gap between adjacent metal wiring lines, to be resistant to moisture transport, and to provide a low dielectric constant for minimizing capacitance between adjacent metal wiring lines. Thus, it is important to modify a deposition to obtain a high quality and void-free IMD layer.

Referring to FIGS. 1A to 1D, U.S. Pat. No. 6,117,345 discloses a method in which high density plasma chemical vapor deposition (HDPCVD) is employed to form the IMD layer between the metal wiring lines. As shown in FIG. 1A, on a semiconductor substrate 10, a surface layer 12, a wiring layer 14, a protection layer 16 and a cap layer 18 are sequentially provided. In addition, a photoresist layer 20 is patterned on the cap layer 18 to expose predetermined regions 22. As shown in FIG. 1B, using the photoresist layer 20 as a mask for etching the cap layer 18, the protection layer 16, the wiring layer 14 and the surface layer 12, a plurality of gaps 26 is formed in the exposed regions 22 respectively. At the same time, the wiring layer 14 is patterned as individual metal wiring lines 24 spaced from the gaps 26.

Next, HDPCVD, at a sufficiently high etch-to-deposition ratio, is performed to form an HDPCVD oxide layer 28. At the early stages of the HDPCVD, the corner of the cap layer 18 is etched away, producing a taper topography of the HDPCVD oxide layer 28 on the top of the cap layer 18. HDPCVD is continually performed until the gaps 26 are filled with the HDPCVD oxide layer 28 reaching the level of the top of the protective layer 16. Next, as shown in FIG. 1D, plasma enhanced chemical vapor deposition (PECVD) deposits a PECVD oxide layer 29 on the entire surface of the HDPCVD oxide layer 28.

Solvents used when removing the photoresist layer 20 easily attack the sidewalls of the metal wiring lines 24, and resulting changes in the pattern of the metal wiring line 24 may decrease conductivity and reduce tolerance to misalignment between the metal wiring line 24 and a contact plug formed in subsequent processes. In addition, adhesion between the metal wiring line 24 and the HDPCVD oxide layer 28 is an important issue. Furthermore, when organic low-k dielectric materials are applied to the use of an IMD layer between the metal wiring lines 24, the outgassing problem of the organic low-k dielectric materials must be solved. A cap layer encapsulating the interconnect structure from the surrounding IMD layer and enhancing the adhesion between the interconnect structure and the IMD layer is called for.

### SUMMARY OF THE INVENTION

The present invention provides an interconnect structure capped with a metallic barrier layer to encapsulate the interconnect structure from the surrounding IMD layer and enhance adhesion between the interconnect structure and the IMD layer. The present invention also provides a corresponding method of fabricating the interconnect structure capped with a metallic barrier layer.

The interconnect structure comprises at least two adjacent metal wiring lines patterned on a semiconductor substrate and spaced from a gap, and a cap layer patterned on each top of the metal wiring lines. A dielectric layer, which may be silicon oxide formed by two-stage CVD including HDPCVD and PECVD, or of organic low-k dielectric materials formed by spin coating, is formed on the metal wiring lines to fill the gap to a predetermined thickness. A metallic barrier layer, which may be Ti, TiN, Ta, TaN, Cu or copper alloys is sandwiched between the sidewall of the metal wiring line and the dielectric layer. In addition, a contact plug passing through the dielectric layer is electrically connected to the top of the metal wiring line.

In the method of fabricating the interconnect structure, adjacent metal wiring lines spaced from a gap are patterned on the semiconductor substrate, wherein the cap layer is patterned on the top of the metal wiring layer. Then, the metallic barrier layer is deposited on the exposed surface of the metal wiring lines, the cap layer and the semiconductor substrate. Using anisotropic etching, the metallic barrier layer is retained on the sidewalls of the metal wiring lines, thus exposing the semiconductor substrate within the gap. Next, the dielectric layer is formed to fill the gap and reach a predetermined thickness. After planarizing the top of the dielectric layer, a via hole passing through the dielectric layer and the cap layer is formed to expose the top of the metal wiring line. Finally, a conductive layer filling the via hole serves as a contact plug.

Accordingly, it is a principal object of the invention to provide a metallic barrier layer to compensate for degeneration in the sidewalls of the metal wiring lines from the effects of cleaning solvents.

It is another object of the invention to ensure the required conductivity of the metal wiring lines.

Yet another object of the invention is to provide a larger contact area to the contact plug so as to increase the tolerance of misalignment between the metal wiring line and the contact plug.

It is a further object of the invention to provide a metallic barrier layer to increase adhesion between the metal wiring line and the dielectric layer.

Still another object of the invention is to provide the metallic barrier layer 46 to prevent outgassing from the dielectric layer.

These and other objects of the present invention will become readily apparent upon further review of the following specification and drawings.

### BRIEF DESCRIPTION OF THE DRAWINGS

FIGS. 1A to 1D are cross-sectional diagrams showing a conventional method employing HDPCVD to form the IMD layer between the metal wiring lines.

FIGS. 2A to 2I are cross-sectional diagrams showing a method of fabricating an interconnect structure according to the present invention.

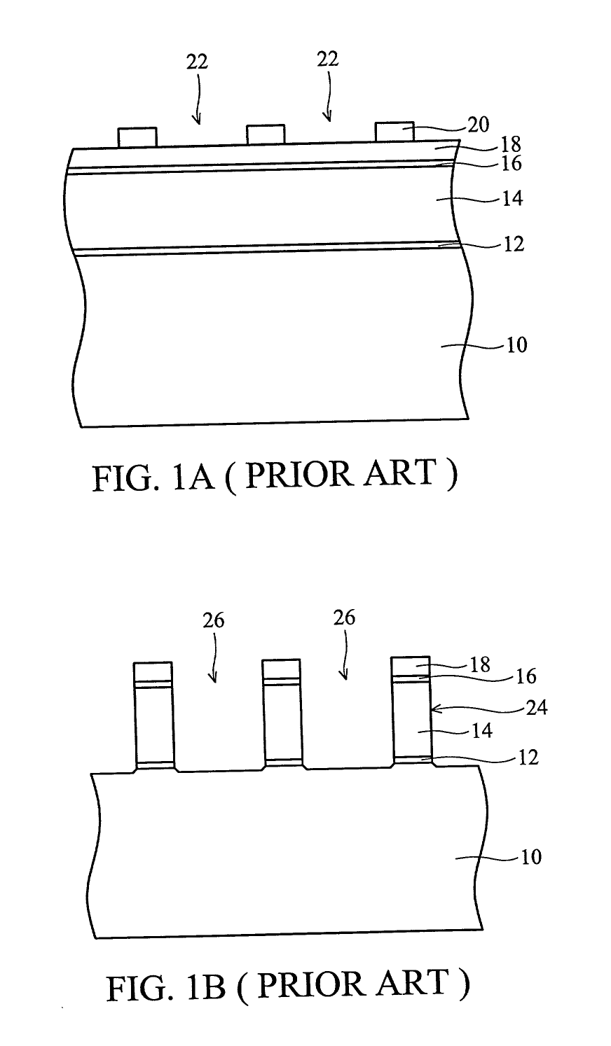

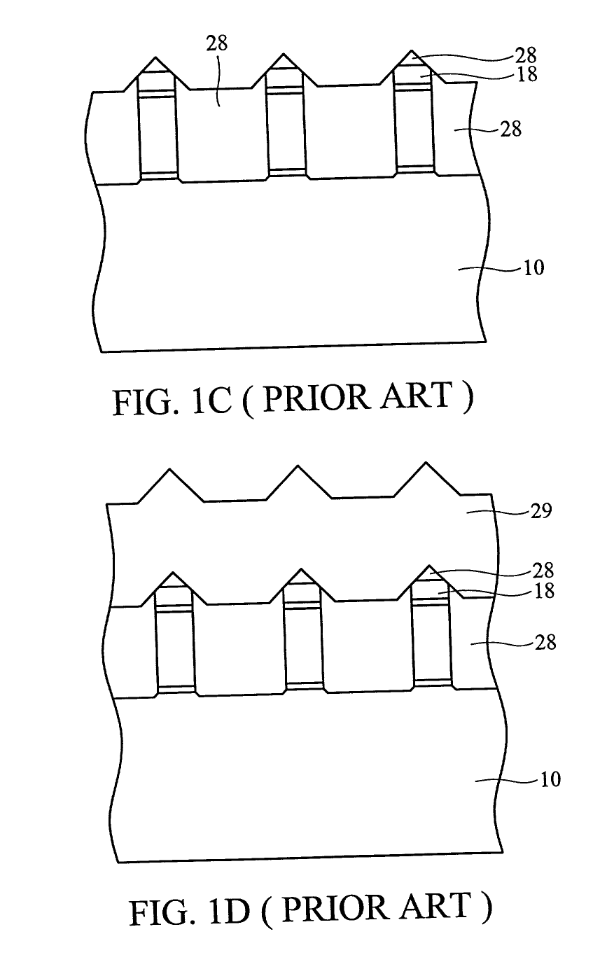

Similar reference characters denote corresponding features consistently throughout the attached drawings.

### DETAILED DESCRIPTION OF THE PREFERRED EMBODIMENTS

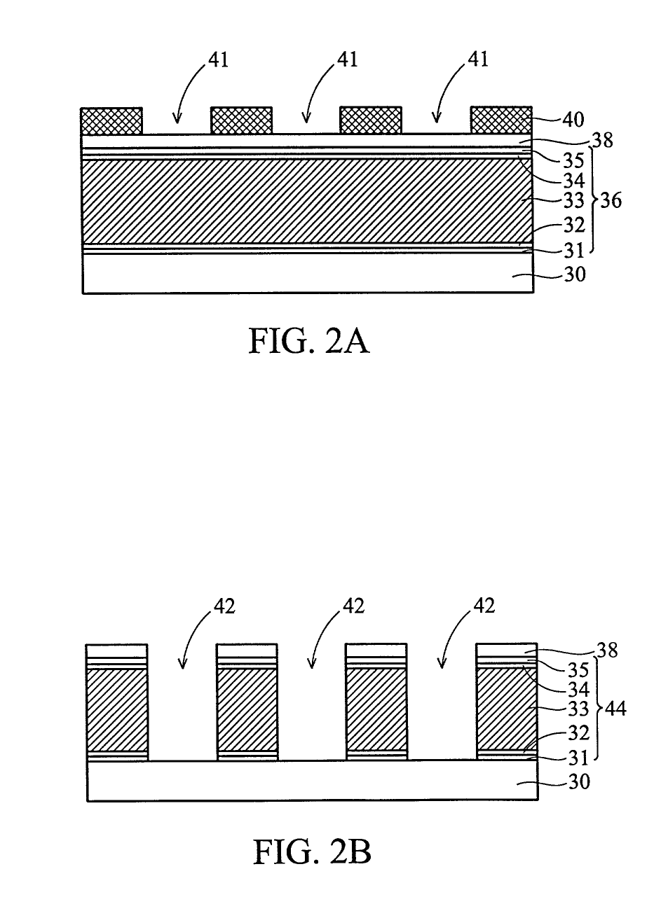

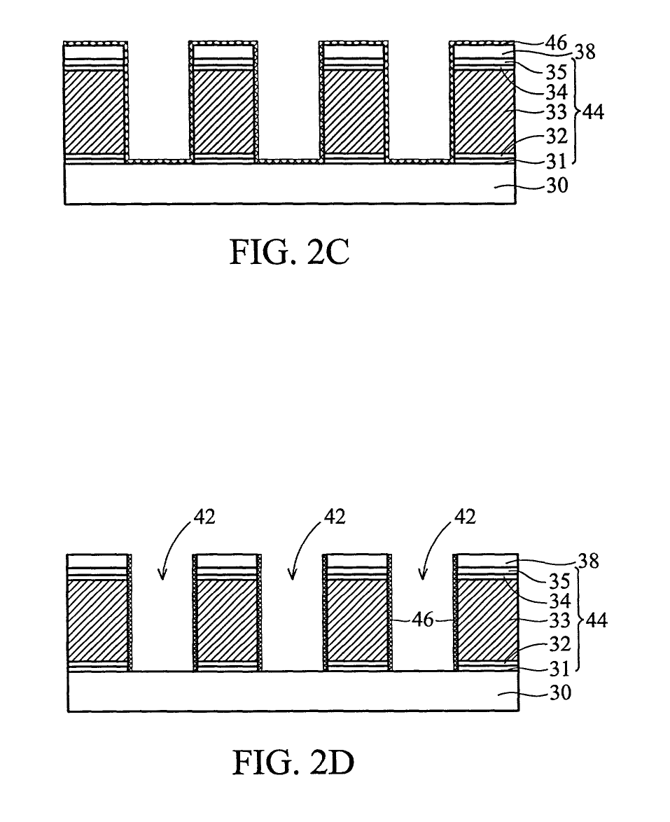

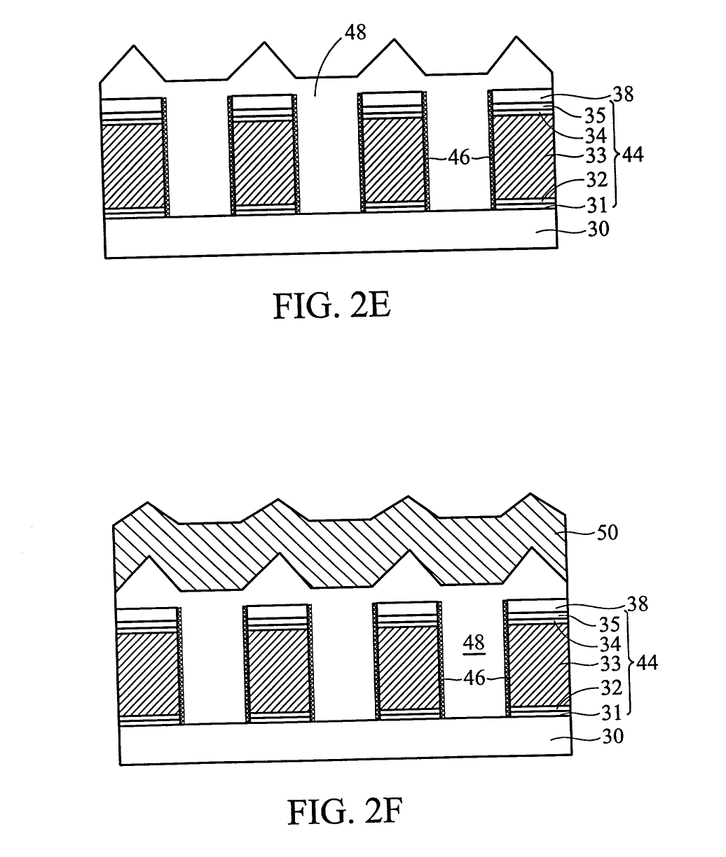

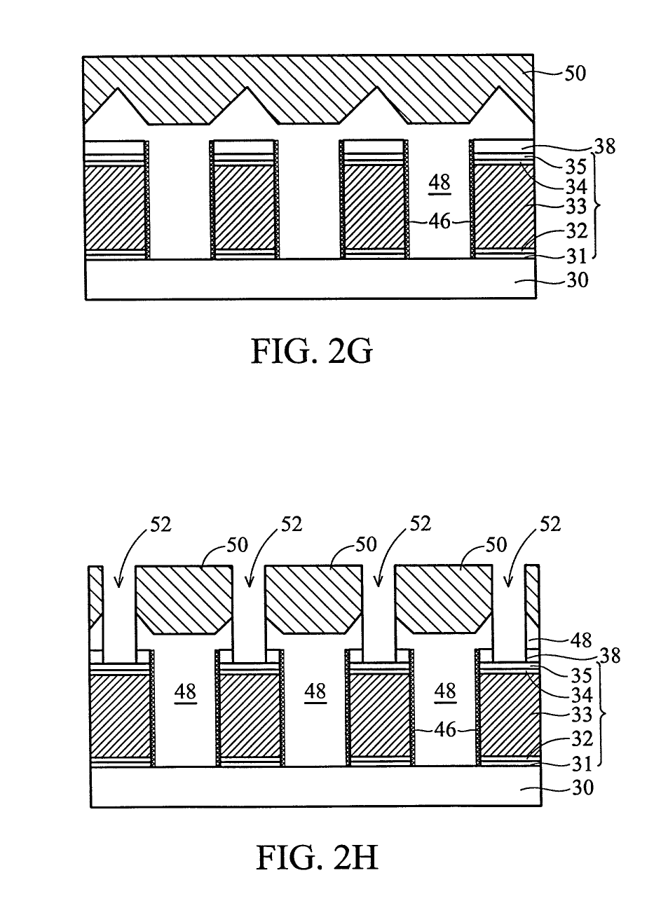

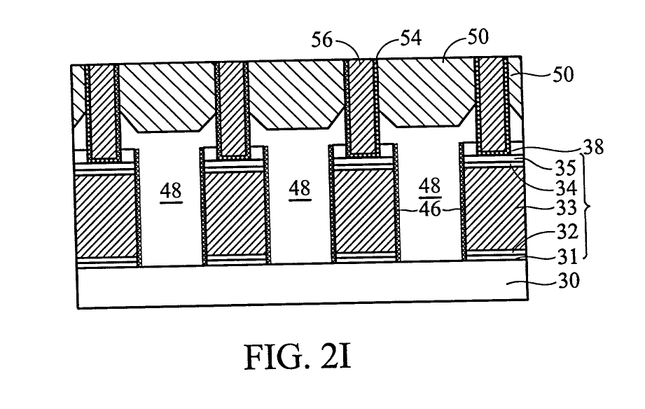

FIGS. 2A to 2I are cross-sectional diagrams showing a method of fabricating an interconnect structure according to the present invention. As shown in FIG. 2A, a semiconductor substrate 30 is provided, possibly containing, for example, transistors, diodes, and other semiconductor elements as well known in the art, and other metal interconnect layers. A metal wiring line layer 36 deposited on the semiconductor substrate 30 may be a variety of materials, such as aluminum, aluminum alloyed with silicon or copper, copper alloys, and multilayer structures. Preferably, the metal wiring line layer 36 is a multilayer structure with a first Ti layer 31, a first TiN layer 32, a AlCu layer 33, a second Ti layer 34, and a second TiN layer 35 sequentially formed on the semiconductor substrate 30.

In addition, a cap layer 38 is formed on the wiring layer 36, and a photoresist layer 40 is patterned on the cap layer 38 to expose predetermined regions 41. The cap layer 38, preferably of SiON, may serve as a quarter wave plate during the exposure of the photoresist layer 40 in order to prevent light from passing through the cap layer 38 and prevent light from reflecting back up to the photoresist layer 40. Also, the cap layer 38 may serve as a hard mask for etching the metal wiring line layer 36 in subsequent etching. Furthermore, the cap layer 38 may serve as a protector to avoid the top corner of individual metal wiring lines from etching during the subsequent HDPCVD.

Referring to FIG. 2B, by consecutively etching the cap layer 38, the layers 35, 34, 33, 32 and 31 from the exposed regions 41, the metal wiring line layer 36 is patterned to become a plurality of individual metal wiring lines 44 spaced from a plurality of gaps 42. The photoresist layer 40 is then removed. Then, as shown in FIG. 2C, a metallic barrier layer 46 is conformally deposited on the entire surface of the semiconductor substrate 30. Next, as shown in FIG. 2D, using anisotropic etching, such as reactive ionized etcher (RIE), the metallic barrier layer 46 formed at the bottom of the gaps 42 is completely removed to expose the semiconductor substrate 30. Meanwhile, the metallic barrier layer 46 formed on the top of the cap layer 38 may be etched away depending on process control. Therefore, the remaining part of the metallic barrier layer 46 covers the sidewalls of the metal wiring lines 44.

The metallic barrier layer 46 may be of Ti, TiN, Ta, TaN, Cu, or copper alloys, and may be formed through CVD, PVD or electroplating. One purpose of the metallic barrier layer 46 is to compensate for degeneration in the sidewalls of the metal wiring lines 44 from the effects of cleaning solvents when removing the photoresist layer 40. This can ensure the required conductivity of the metal wiring lines 44. Also, this can provide a larger contact area to a contact plug formed in the subsequent processes, thus increases the tolerance of misalignment between the metal wiring line 44 and the contact plug. Another purpose of the metallic barrier layer 46 is to increase the adhesion between the metal wiring line 44 and an IMD layer formed in the subsequent processes. Still another purpose of the metallic barrier layer 46 is to prevent the outgassing effect from the IMD layer, especially when organic low-k materials are used to form the IMD layer.

Referring to FIG. 2E, using high density plasma chemical vapor deposition (HDPCVD), a HDPCVD oxide layer 48 is formed on the metal wiring lines 44 to completely fill the gaps 42. Since the HDPCVD may accomplish both deposition and etching at the same time, a taper topography of the HDPCVD oxide layer 48 is produced over the cap layer 38. Then, as shown in FIG. 2F, using plasma enhanced chemical vapor deposition (PECVD), a PECVD oxide layer 50 is deposited on the entire surface of the HDPCVD oxide layer 48 to a predetermined thickness. The top surface of the PECVD oxide layer 50 presents corresponding topography. In another preferred embodiment, organic low-k dielectric materials selected from spin-on polymer (SOP), such as FLARE, SILK, Parylene, or PAE-II, and formed through spin-coating can substitute the HDPCVD oxide layer 48 and the PECVD oxide layer 50.

Referring to FIG. 2G, CMP is performed to planarize the top of the PECVD oxide layer 50, therefore a global planarization layer is provided for the subsequent contact plug. The HDPCVD oxide layer 48 and the PECVD oxide layer 50 surrounding the metal wiring lines 44 serve as the IMD layer.

Hereinafter, the contact plug process is provided on the planarized surface of the PECVD oxide layer 50. Contact plug fabrication methods are a design choice dependent on the individual overall fabrication employed. Referring to FIG. 2H, using photolithography and etching, the PECVD oxide layer 50, the HDPCVD oxide layer 48 and the cap layer 38 are consecutively removed to from a plurality of via holes 52 which expose the tops of the metal wiring lines 44 respectively. Referring to FIG. 2I, a barrier layer 54 of Ti, TiN, Ta or TaN is deposited on the sidewall and bottom of each via hole 52, and then a conductive layer 56 is deposited to fill the via holes 52. The conductive layer 56 may be formed from a variety of materials, such as aluminum, aluminum alloyed with silicon or copper, copper alloys, and multilayer structures. Finally, using the CMP again, the excessive portion outside the level of the via holes 52 is removed, thus the remaining part of the conductive layer 56 in each via hole 52 serves as the contact plug.

It is to be understood that the present invention is not limited to the embodiments described above, but encompasses any and all embodiments within the scope of the following claims.

What is claimed is:

1. An interconnect structure on a semiconductor substrate, comprising:
at least two adjacent metal wiring lines patterned on the semiconductor substrate and spaced from a gap;
a metallic barrier layer formed on the sidewalls of the metal wiring lines;
a dielectric layer formed on the metal wiring lines and the metallic barrier layer and filling the gap to a predetermined thickness; and
a contact plug passing through the dielectric layer and electrically connected to the top of the metal wiring line.

2. The interconnect structure according to claim 1, wherein the dielectric layer is silicon oxide formed by chemical vapor deposition (CVD).

3. The interconnect structure according to claim 1, wherein the dielectric layer is of organic low-k dielectric materials formed by spin coating.

4. The interconnect structure according to claim 1, wherein the dielectric layer comprises:
a first silicon oxide layer formed on the metal wiring lines to fill the gap; and
a second silicon oxide layer formed on the first silicon oxide layer to the predetermined thickness.

5. The interconnect structure according to claim 4, wherein the first silicon oxide layer is formed by high density plasma chemical deposition (HDPCVD).

6. The interconnect structure according to claim 4, wherein the second silicon oxide layer is formed by plasma enhanced chemical deposition (PECVD).

7. The interconnect structure according to claim 1, wherein the metallic barrier layer is of Ti, TiN, Ta, TaN, Cu, or copper alloys.

8. The interconnect structure according to claim 1, further comprising a cap layer on the top of the metal wiring line.

9. A method of fabricating an interconnect structure, comprising steps of:
providing a semiconductor substrate having at least two adjacent metal wiring lines spaced from a gap;
forming a metallic barrier layer on the sidewalls of the metal wiring lines;
forming a dielectric layer on the metal wiring lines to fill the gap and reach a predetermined thickness;
planarizing the top of the dielectric layer;
forming a via hole passing through the dielectric layer and exposing the top of the metal wiring line; and
forming a conductive layer to fill the via hole.

10. The method according to claim 9, wherein the dielectric layer is of silicon oxide by chemical vapor deposition.

11. The method according to claim 9, wherein the dielectric layer is of organic low-k dielectric materials formed by spin coating.

12. The method according to claim 9, wherein the step of forming the dielectric layer comprises:
forming a first silicon oxide layer on the metal wiring lines to fill the gap; and
forming a second silicon oxide layer on the first silicon oxide layer to the predetermined thickness.

13. The method according to claim 12, wherein the first silicon oxide layer is formed by high density plasma chemical deposition (HDPCVD).

14. The method according to claim 12, wherein the second silicon oxide layer is formed by plasma enhanced chemical deposition (PECVD).

15. The method according to claim 9, wherein the metallic barrier layer is of Ti, TiN, Ta, TaN, Cu, or copper alloys.

16. The method according to claim 9, wherein the step of forming the metallic barrier layer comprises:
depositing the metallic barrier layer on the exposed surface of the metal wiring lines and the semiconductor substrate; and
removing the metallic barrier layer positioned on the exposed surface of the semiconductor substrate.

17. The method according to claim 9, wherein the dielectric layer is planarized by chemical mechanical polishing (CMP).

18. The method according to claim 9, wherein the semiconductor substrate further comprises a cap layer on each top of the metal wiring lines.
